(19) United States
(12) Patent Application Publication
(10) Pub. No.: US 2004/0104444 A1
(43) Pub. Date: Jun. 3, 2004

(54) MEMS device with alternative electrical connections

(76) Inventors: Bruce K. Wachtmann, Concord, MA (US); David J. Collins, Pelham, NH (US); Thomas D. Chen, Malden, MA (US)

Correspondence Address: Steven G. Saunders, Bromberg & Sunstein LLP, 125 Summer Street, Boston, MA, 02110-1618, US

(21) Appl. No.: 10/308,688

(22) Filed: Dec. 3, 2002

(51) Int. Cl. H01L 27/14

(52) U.S. Cl. 257/414

(57) ABSTRACT

A MEMS device has a first silicon layer, a second silicon layer, and an insulating layer between the first and second silicon layers. The first silicon layer has at least a primary portion and an isolated portion, where the isolated portion has no electrical connection with the primary portion via the first silicon layer. The MEMS device also has a conductive element within the insulating layer. The conductive element is in electrical contact with both the primary portion and the isolated portion.

### FIELD OF THE INVENTION

The invention generally relates microelectromechanical systems and, more particularly, the invention relates to electrical connections on microelectromechanical systems.

### BACKGROUND OF THE INVENTION

Microelectromechanical systems (“MEMS”) are used in a growing number of applications. For example, MEMS currently are implemented as gyroscopes to detect pitch angles of airplanes, and as accelerometers to selectively deploy air bags in automobiles. In simplified terms, such MEMS devices typically have a structure suspended above a substrate, and associated electronics that both senses movement of the suspended structure and delivers the sensed movement data to one or more external devices (e.g., an external computer). The external device processes the sensed data to calculate the property being measured (e.g., pitch angle or acceleration).

The electronics and suspended structure typically are formed (by conventional etching processes) from the top layer of a multi-layered wafer. Problems arise during manufacture, however, when one portion of the top layer is electrically isolated from the remainder of the top layer, and/or not readily accessible to the edges of the device. In particular, from a design and manufacturing perspective, it is difficult to electrically connect such portion (referred to as an “island” or “isolated portion”) to other portions of the top layer. One solution to this problem is to snake an insulated line across the tortuous path leading to the isolated portion. This process generally is cumbersome, however, consequently increasing production costs.

### SUMMARY OF THE INVENTION

In accordance with one aspect of the invention, a MEMS device has a first silicon layer, a second silicon layer, and an insulating layer between the first and second silicon layers. The first silicon layer has at least a primary portion and an isolated portion, where the isolated portion has no electrical connection with the primary portion via the first silicon layer. The MEMS device also has a conductive element within the insulating layer. The conductive element is in electrical contact with both the primary portion and the isolated portion.

The MEMS device also may include an electrically conductive path formed between the primary portion and the conductive element, and another electrically conductive path between the isolated portion and the conductive element. In illustrative embodiments, the isolated portion may have a movable structure with a non-movable portion, where the electrically conductive path includes an anchor that contacts the movable structure at its non-movable portion.

Among other things, the insulating layer may have an etched insulator material and an air space between the first and second silicon layers. Moreover, the first layer may include at least one of electronics and movable structure. In such case and in other cases, the MEMS device may be a SOI-based (i.e., silicon-on-insulator based) device. The primary portion may have an interface to transmit electrical signals to, and receive electrical signals from, electronics formed by the first silicon layer. The electrical signals may be transmitted between the isolated portion and the primary portion via the conductive element.

In accordance with another aspect of the invention, a MEMS device having a plurality of layers includes a first layer having at least a primary portion and an isolated portion, a second layer, and a conductive element in contact with the second layer. The conductive element electrically connects the primary portion and the isolated portion.

In illustrative embodiments, the conductive element is spaced from the first layer. In addition, the MEMS device may include a third layer, where the second layer is between the first and third layers. The first layer may be silicon and the second layer may be an insulator (e.g., an oxide). The second layer illustratively contacts the first layer. In some embodiments, the MEMS device has a first electrical connector extending between the conductive element and the isolated portion. The electrical connector may form an anchor on a non-movable portion of the isolated portion. More generally, the MEMS device may have an anchor extending from the isolated portion to the conductive element. The anchor electrically connects the conductive element with the isolated portion.

### BRIEF DESCRIPTION OF THE DRAWINGS

The foregoing and advantages of the invention will be appreciated more fully from the following further description thereof with reference to the accompanying drawings wherein:

FIG. 1 schematically shows a top view of a MEMS device that may be configured in accordance with illustrative embodiments of the invention.

FIG. 2 schematically shows a cross-sectional view of the MEMS device along line X-X.

FIG. 3 shows a process of producing the MEMS device shown in figure

FIG. 4 schematically shows a cross-sectional view of a wafer formed with an internal electrode.

FIG. 5 schematically shows a cross-sectional view of the wafer of FIG. 4 with an isolation trench.

FIG. 6 schematically shows a cross-sectional view of the (processed) wafer shown in FIG. 5 with anchors formed therein.

FIG. 7 schematically shows a cross-sectional view of the (processed) wafer shown in FIG. 6 with electronics formed thereon.

FIG. 8 schematically shows a cross-sectional view of the (processed) wafer shown in FIG. 7 with etched beams.

FIG. 9 schematically shows a cross-sectional view of an alternative embodiment of the invention.

### DESCRIPTION OF ILLUSTRATIVE EMBODIMENTS

In illustrative embodiments, a MEMS device includes an internal conductor that electrically connects otherwise electrically isolated portions of the MEMS device. In some embodiments, the internal conductor also acts as an anchor for a movable portion of a MEMS device. To these ends, in such embodiments, a multi-layer MEMS device has an internal layer that contains the internal conductor, a conductive path leading from the isolated portion to the internal conductor, and another conductive path leading from another portion of the MEMS device to the internal conductor. The two conductive paths and the internal conductor provide an electrical pathway between the two portions of the MEMS device. Accordingly, electrical signals may be exchanged between the two MEMS portions. Details of illustrative embodiments are discussed below.

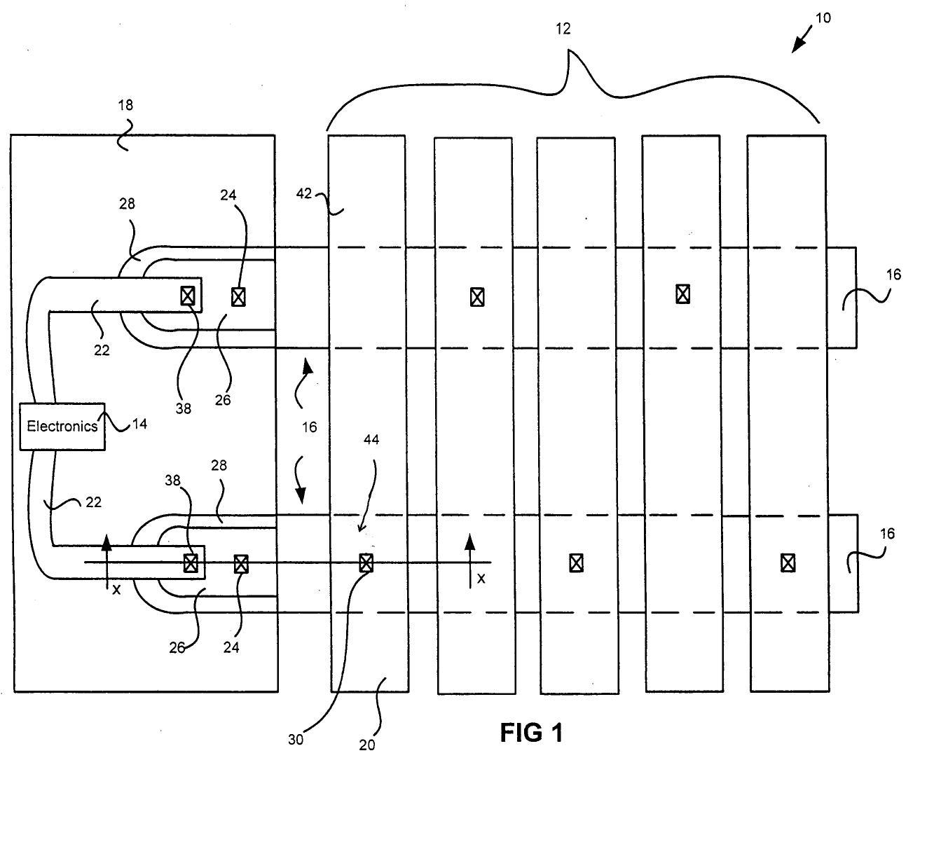

FIG. 1 schematically shows a MEMS device 10 that may be configured in accordance with various embodiments of the invention. In illustrative embodiments, the MEMS device 10 is implemented as a gyroscope. Accordingly, for illustrative purposes, various embodiments are discussed herein as a MEMS gyroscope. The MEMS device 10 thus is identified in this description and in the drawings as gyroscope 10 or MEMS device 10. It should be noted, however, that discussion of various embodiments as a gyroscope is exemplary only and thus, not intended to limit all embodiments of the invention. Accordingly, some embodiments may apply to other types of MEMS devices, such as optical switching devices and accelerometers.

In illustrative embodiments, the MEMS device 10 includes both mechanical structure to sense angular rotation, and corresponding electronics to process such sensed rotation. This entire functionality is located on a single die. Some embodiments, however, may apply to MEMS devices having the structure only, or the electronics only. The structure and electronics (both shown schematically in the drawings) illustratively are formed on a silicon-on-insulator (“SOI”) wafer, which has an oxide layer between a pair of silicon layers.

The mechanical structure may include one or more vibrating masses suspended above a silicon substrate by a plurality of flexures (not shown). The structure also may include a comb drive and sensing apparatus to both drive the vibrating masses and sense their motion. In a corresponding manner, the electronics may include, among other things, the driving and sensing electronics that couple with the comb drive and sensing apparatus, and signal transmission circuitry. Wires electrically connect the accompanying electronics with pins on an exterior package (not shown). For simplicity, the electronics are shown schematically at reference number 14, while the mechanical structure is shown schematically at reference number 12.

Exemplary MEMS gyroscopes are discussed in greater detail in co-pending provisional and non-provisional U.S. patent applications identified by serial Nos. 60/364,322, 60/354,610, and 10/234,215, each of which are assigned to Analog Devices, Inc. of Norwood, Mass. The disclosures of these noted provisional and non-provisional patent applications are incorporated herein, in their entireties, by reference.

In accordance with illustrative embodiments of the invention, the MEMS device 10 includes an internal conductive element (identified by reference number 16) that electrically connects a primary portion 18 of the MEMS device 10 with an electrically isolated portion 20 of the MEMS device 10. This connection consequently electrically connects the isolated portion 20 with the electronics 14.

More specifically, the primary portion 18 is electrically connected to 1) the electronics 14 via a metal lead 22, and 2) the internal conductive element 16 via a first conductive path 24 (e.g., a staple). The first conductive path 24 is isolated from the remainder of the primary portion 18 within an interface area 26 that is surrounded by a nitride isolation trench 28. The conductive element 16 extends within the MEMS device 10 underneath the prior noted mechanical structure 12. At least a portion of such mechanical structure 12 is the noted isolated portion 20, which otherwise is electrically isolated from the primary portion 18. In other words, absent the internal conductive element 16, the isolated portion 20 is electrically isolated from the primary portion 18. Accordingly, as discussed below in greater detail, the isolated portion 20 includes a second conductive path 30 (e.g., an anchor and/or a staple) that contacts the internal conductive element 16, thus electrically connecting the isolated portion 20 to the primary portion 18.

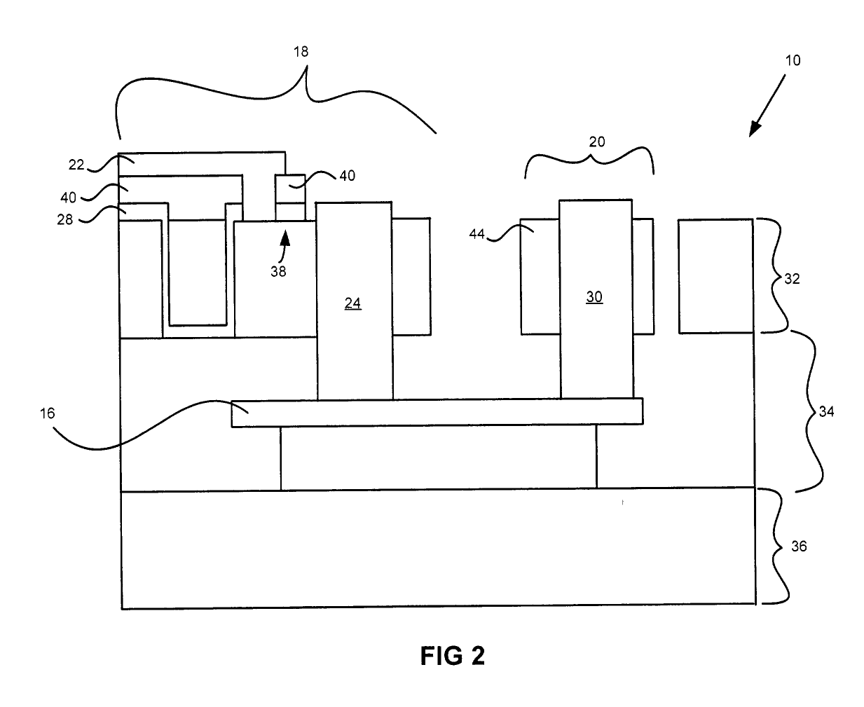

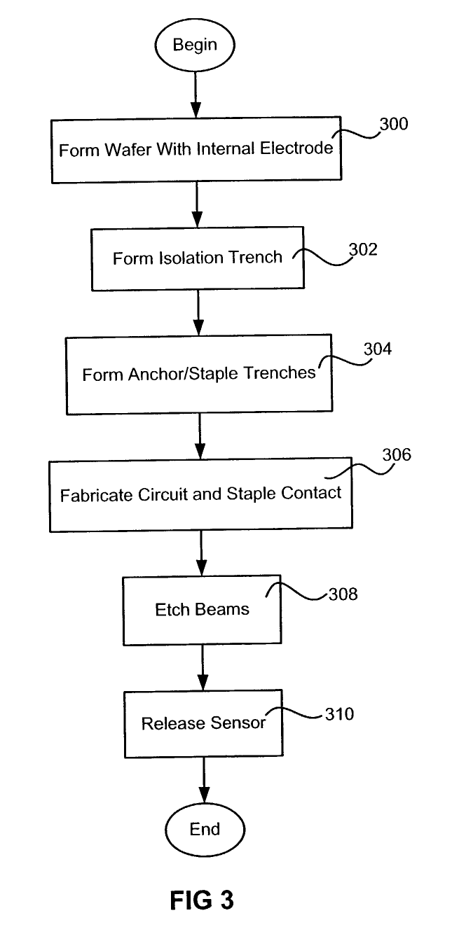

Additional details of the MEMS device 10 are shown in its cross-sectional view. Specifically, FIG. 2 schematically shows a cross-sectional view of the MEMS device 10 of FIG. 1 along line X-X. As shown, the MEMS device 10 has three layers; namely, a top layer 32 having the electronics 14 and mechanical structure 12, an insulator layer 34 having the internal conductive element 16, and a bottom layer 36 acting as a support substrate. The top and bottom layers 32 and 36 may be manufactured from a semiconductor (e.g., polysilicon, single crystal silicon, or amorphous silicon), while the insulator layer 34 may be manufactured from an insulator, such as an oxide. As known by those in the art, conventional manufacturing processes (discussed below) remove and etch portions of different layers to form the final MEMS device 10. Details of this process are discussed below with reference to FIGS. 3-8.

Among other portions, the top layer 32 is considered to have the above noted primary and isolated portions 18 and 20. The primary portion 18 includes a contact 38 for receiving an electrical signal from the electronics 14 via the metal lead 22, and the noted first conductive path 24 extending to the conductive element 16 in the insulator layer 34. A second insulator 40 (e.g., silicon dioxide) is applied below the metal lead 22 (i.e., to the top surface of the top layer 32) to electrically isolate the metal lead 22 from all of the primary portion 18 except the contact 38. As discussed in greater detail below, the first conductive path 24 may be a conductor or semi-conductor material, such a polysilicon. In addition, the primary portion 18 includes the above noted conventional isolation trench 28 to isolate the contact 38 and conductive path from the remainder of the primary portion 18.

The isolated portion 20 includes movable structure 12 (e.g., fingers of a comb drive) and the second conductive path 30 extending to the conductive element 16 in the insulator layer 34. In a manner similar to the first conductive path 24 (extending through the primary portion 18), the second conductive path 30 also is manufactured from a conductive or semiconductor material, such as polysilicon. Consequently, the first conductive path 24, conductive element 16, and the second conductive path 30 together form an electrical pathway to electrically connect the primary portion 18 with the isolated portion 20.

The isolated portion 20 thus may communicate with the electronics 14 via the metal lead 22, contact 38, and electrical pathway. Among other things, such signals may be control signals to actuate the comb drive, or data signals having sensed capacitance information. The conductive element 16 thus effectively electrically connects the otherwise electrically isolated portion 20 of the top layer 32 with the primary portion 18. In various embodiments, the isolated portion 20 is bounded on all sides by other portions of the top surface (i.e., it effectively forms an island on the top layer 32). In such case, the isolated portion 20 is not readily accessible to the edges of the MEMS device 10. Using the conductive element 16 within the insulator layer 34 thus provides a more effective means for electrically connecting the isolated portion 20 with the electronics 14.

Because it has movable structure 12, the isolated portion 20 may have both a movable portion 42 and a non-movable portion 44. In illustrative embodiments, the second conductive path 30 extends through the non-movable portion 44 of the isolated portion 20. Consequently, the second conductive path 30 performs the dual functions of an anchor and a conductive path. In other embodiments, the conductive path does not perform the function of an anchor.

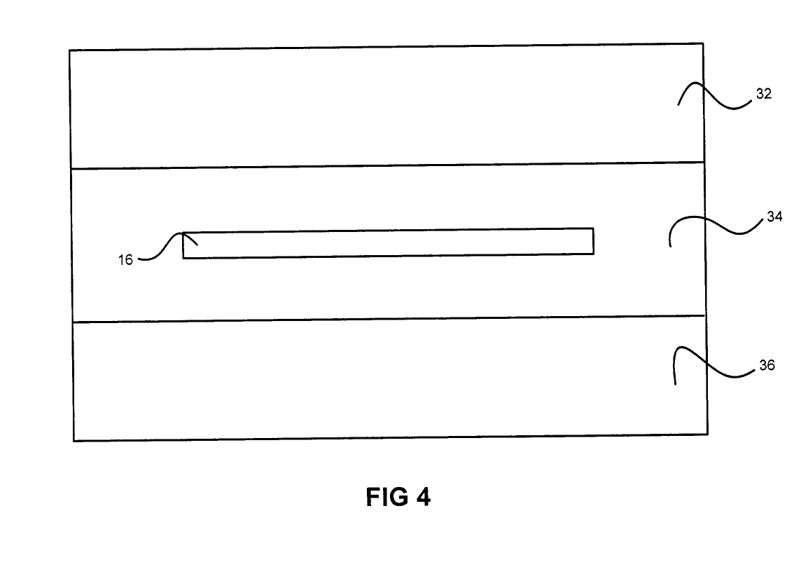

FIG. 3 shows an exemplary process of producing the MEMS device 10 shown in FIGS. 1-2. FIGS. 4-8 schematically show the MEMS device 10 in various stages of development to graphically illustrate the process of FIG. 3. The process begins at step 300, in which an SOI wafer is formed with an internal electrode (i.e., the internal conductive element 16). To that end, a two-layer wafer comprising a polysilicon layer and an oxide layer is mated to another identical two-layer wafer by conventional processes. The wafers are mated, however, so that the conductive element 16 is mounted between the two facing oxide layers. As shown in FIG. 4, conventional processes cause the oxide layers to effectively form a single oxide layer that encapsulates the conductive element 16.

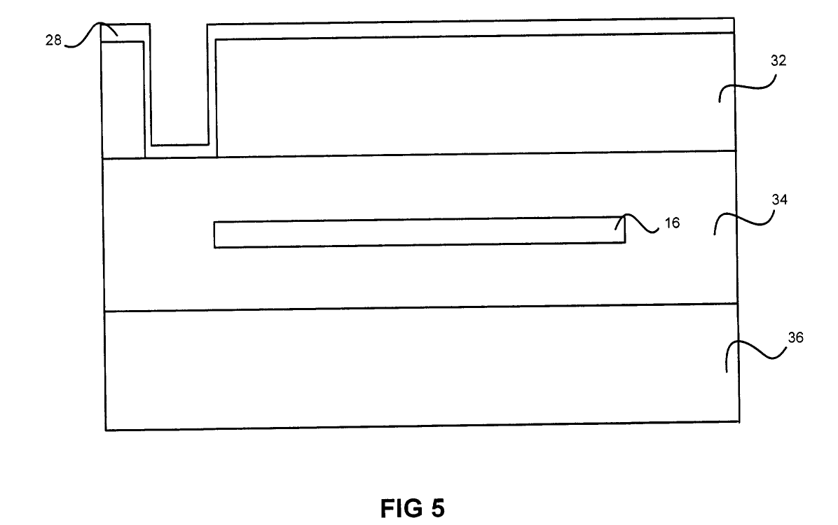

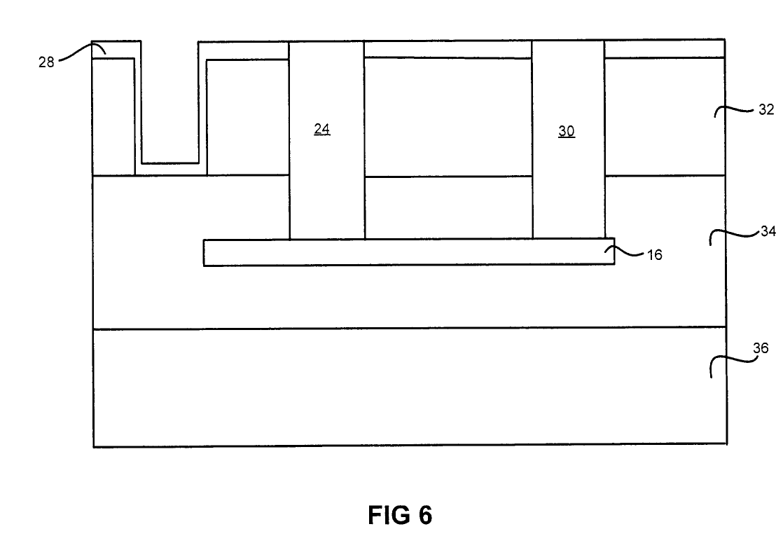

The process continues to step 302, in which the isolation trench 28 is formed. As shown in FIG. 5, the isolation trench 28 may be formed by etching through the top layer 32, and injecting a nitride liner and polysilicon (or other suitable fill material) in the etched area. After the trench is formed, the anchor/staple trenches are formed (step 304, FIG. 6). Specifically, the anchor/staple trenches are formed through the top layer 32 and oxide layer, and stop at the conductive element 16. After the trenches are formed, a conductive or semi-conductor material is added to form the first and second conductive paths 24 and 30. In illustrative embodiments, the material added to the trenches is a polysilicon doped in the same manner as the top layer 32 (e.g., all doped as P-type silicon). Although they are the same dopant types, however, the conductive paths may have a different concentration than that of the top layer 32. Because of their functions, the first and second conductive paths 24 and 30 may be referred to herein as staples or anchors.

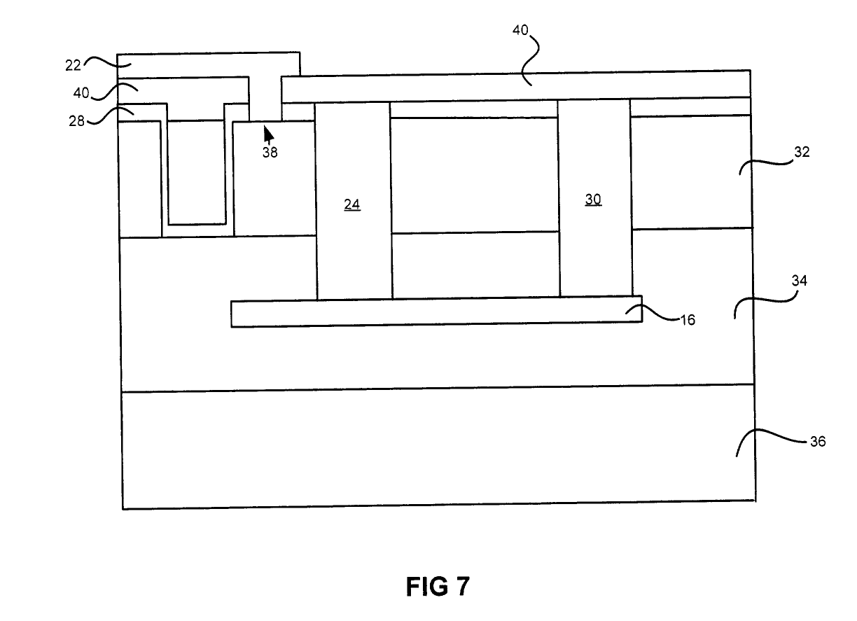

After the anchors are formed, the electronics 14 and contact 38 may be fabricated on the primary portion 18 of the top layer 32 (step 306, FIG. 7). In some embodiments, however, the electronics 14 may be formed on a different portion, or even on a different die, than the primary portion 18. In either case, the electronics 14 communicates with the primary portion 18. In other embodiments, the metal lead 22 merely provides power to some component on the isolated portion 20 and thus, does not couple the isolated portion 20 to the electronics 14.

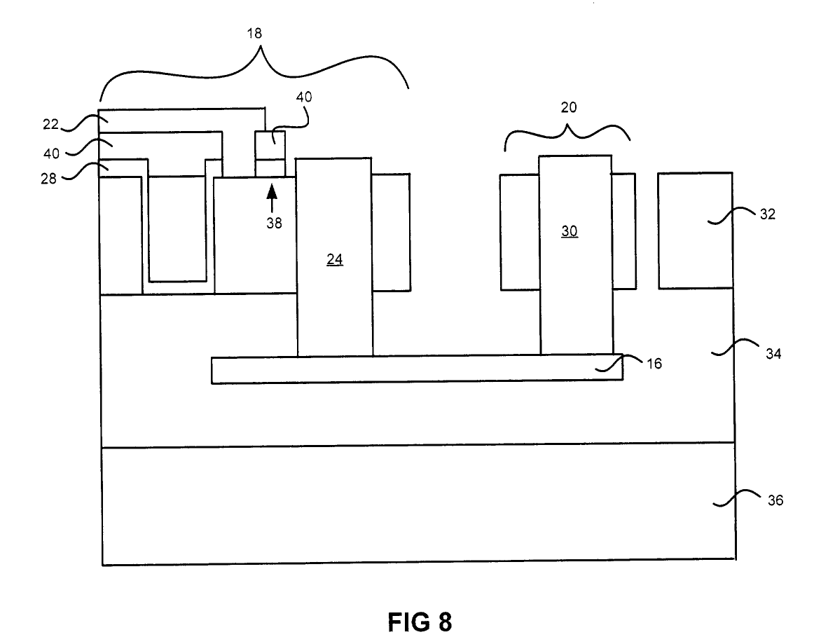

The process then continues to step 308, in which the mechanical structure 12 (e.g., beams) are etched from the top layer 32 (see FIG. 8). This step thus produces a space between the different structural components, thus causing discontinuities in the top layer 32. After it is formed, the structure 12 is released by removing selected portions of the insulator layer 34. In illustrative embodiments, an acid is used to remove the selected portions of the insulator layer 34. This step thus permits selected portions of the structure 12 to be suspended above the bottom “handle” layer (step 310, see FIG. 2), consequently completing the process.

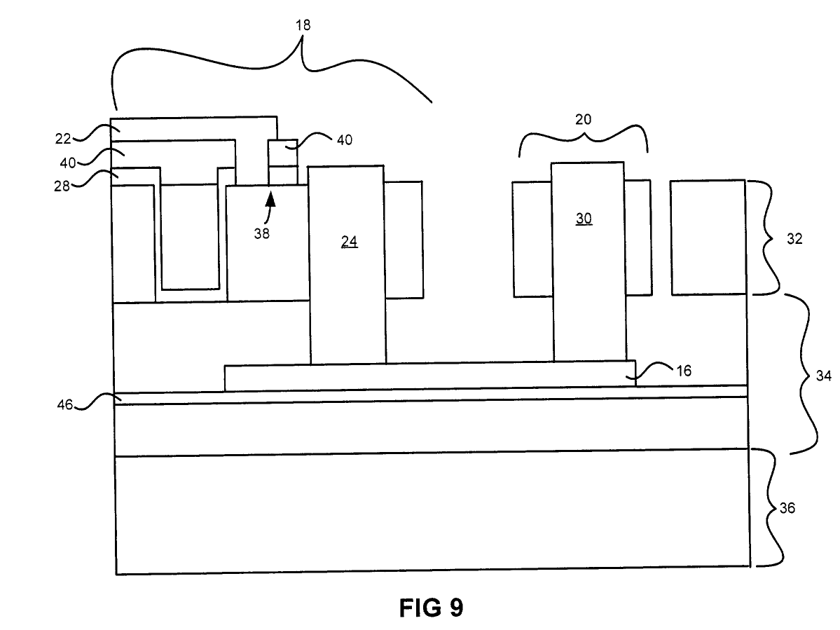

FIG. 9 shows an alternative embodiment of the invention, in which a barrier layer 44 (e.g., formed from nitride) is included immediately below the conductive element 16. The barrier layer 44 forms a barrier that prevents acid from removing the insulator material below it during manufacture. Accordingly, the conductive element 16 has the complete structural support of the insulator material below it.

It should be noted that the MEMS device 10 may be produced with a plurality of conductive elements to electrically connect a number of different portions of the top layer 32. In fact, in some embodiments, the conductive element 16 may electrically couple, two portions that are accessible to the edges of the MEMS device 10. Moreover, the shape and size of the conductive element 16 is selected based upon the specific requirements of the MEMS device 10. In yet other embodiments, the conductive element 16 may electrically connect more than two portions of the MEMS device 10.

Discussion of an SOI based MEMS device is exemplary and thus, not intended to limit all embodiments of the invention. Accordingly, in some embodiments, non-SOI based MEMS devices may use the conductive element 16 to electrically connect various portions of their respective top layers. It also is contemplated that some embodiments may not completely encapsulate the conductive element 16 within the insulator. In such embodiments, the insulator may be in contact with one of the boundaries of the insulator layer 34, and otherwise be insulated from the other conductive layers.

Although various exemplary embodiments of the invention are disclosed below, it should be apparent to those skilled in the art that various changes and modifications can be made that will achieve some of the advantages of the invention without departing from the true scope of the invention.

What is claimed is:

1. A MEMS device comprising:
a first silicon layer having at least a primary portion and an isolated portion, the isolated portion having no electrical connection with the primary portion via the first silicon layer;
a second silicon layer;
an insulating layer between the first and second silicon layers; and
a conductive element within the insulating layer, the conductive element being in electrical contact with both the primary portion and the isolated portion.

2. The MEMS device as defined by claim 1 further comprising an electrically conductive path formed between the primary portion and the conductive element.

3. The MEMS device as defined by claim 1 further comprising an electrically conductive path formed between the isolated portion and the conductive element.

4. The MEMS device as defined by claim 3 wherein the isolated portion includes movable structure with a non-movable portion.

5. The MEMS device as defined by claim 4 wherein the electrically conductive path includes an anchor that contacts the movable structure at the non-movable portion of the movable structure.

6. The MEMS device as defined by claim 1 wherein the insulating layer includes an etched insulator material and an air space between the first and second silicon layers.

7. The MEMS device as defined by claim 1 wherein the first layer includes at least one of electronics and movable structure, the MEMS device being a SOI-based device.

8. The MEMS device as defined by claim 1 wherein the primary portion includes an interface to transmit electrical signals to, and receive electrical signals from, electronics formed by the first silicon layer, the electrical signals being transmitted between the isolated portion and the primary portion via the conductive element.

9. A MEMS device having a plurality of layers, the MEMS device comprising:
a first layer having at least a primary portion and an isolated portion;
a second layer; and
a conductive element in contact with the second layer, the conductive element electrically connecting the primary portion and the isolated portion.

10. The MEMS device as defined by claim 9 further comprising a first electrical connector extending between the conductive element and the isolated portion, the isolated portion including a movable portion and a non-movable portion, the electrical connector forming an anchor on the non-movable portion.

11. The MEMS device as defined by claim 9 wherein the conductive element is spaced from the first layer.

12. The MEMS device as defined by claim 9 wherein the conductive element is within the second layer, the second layer including at least one of a material and an air space.

13. The MEMS device as defined by claim 9 further comprising a third layer, the second layer being between the first and third layers.

14. The MEMS device as defined by claim 9 wherein the first layer is silicon and the second layer is an insulator, the second layer being in contact with the first layer.

15. A MEMS device as defined by claim 9 further comprising an anchor extending from the isolated portion to the conductive element, the anchor electrically connecting the conductive element with the isolated portion.

16. A MEMS device having a plurality of layers, the MEMS device comprising:
a first layer having at least a primary portion and an isolated portion, the isolated portion having no electrical connection with the primary portion via the first layer;
a second layer; and
means for electrically connecting the primary portion and the isolated portion via the second layer.

17. The MEMS device as defined by claim 16 wherein the electrically connecting means includes a conductive element in contact with the second layer, the conductive element being an anchor to a non-movable part of the isolated portion.

18. The MEMS device as defined by claim 17 further including:
means for electrically connecting the primary portion with the conductive element; and
means for electrically connecting the isolated portion with the conductive element.

19. The MEMS device as defined by claim 16 wherein the second layer includes at least of one of an insulator material and an air space.

20. The MEMS device as defined by claim 16 wherein the isolated portion includes means for detecting acceleration, the primary portion including means for transmitting electrical signals to the isolated portion.
